(19) United States
(12) Patent Application Publication
(10) Pub. No.: US 2005/0271951 A1
(43) Pub. Date: Dec. 8, 2005

(54) Plasma etching apparatus and method of fabricating photomask using the same

(76) Inventor: Mi-Young Kim, Hwaseong-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/097,207

(22) Filed: Apr. 4, 2005

(30) Foreign Application Priority Data
Jun. 3, 2004 (KR) 2004-40395

(51) Int. Cl. C23C 14/32; C23C 14/00; G06F 17/50; G03C 5/00; G03F 1/00

(52) U.S. Cl. 430/5; 430/322; 716/19; 716/21; 430/323; 430/324; 204/192.12; 204/192.35

(57) ABSTRACT

A plasma etching apparatus includes a scanning type of system made up of a stage on which a substrate is supported, a plasma generator disposed above the stage and movable relative to the stage, a controller connected to the plasma generator to control the physical condition of the plasma produced by the plasma generator, and a memory for storing control data for controlling the physical condition of the plasma. A photomask is fabricated by locally etching a mask layer using a photoresist layer as an etch mask. In this method, the controller controls the plasma generator to generate plasma having different physical conditions in accordance with the position at which the mask layer is being locally etched. Therefore, it is possible to create different etching conditions across the mask layer and to thus minimize non-uniformity in the resulting mask pattern.

### BACKGROUND OF THE INVENTION

1. Field of the Invention

The present invention relates to a method of fabricating a photo-mask used for fabricating a semiconductor integrated circuit and to a plasma etching apparatus used for fabricating the photo-mask.

2. Description of the Related Art

The fabricating of a semiconductor integrated circuit includes a photolithography process of transcribing the image of a circuit pattern from a photo-mask to a photoresist (PR) layer on a wafer. The wafer photoresist pattern (WPR pattern) formed by the photolithography process is used as a mask for etching material lying under the WPR pattern. On the one hand, the line width of the WPR pattern is the technical variable that most determines the degree to which the final semiconductor circuit is integrated. On the other hand, the degree of integration of the circuit is a main technical factor affecting the value of the semiconductor product. Therefore, various research is aimed at minimizing the line width of the WPR pattern.

Moreover, the uniformity of the line width of the WPR pattern significantly affects the product yield; therefore, reducing the line width of the WPR without maintaining uniformity in the line width has no advantages. Accordingly, various techniques have been suggested for improving the uniformity of the line width of the WPR pattern, such as techniques aimed at controlling conditions of the photolithography process.

However, as mentioned above, the WPR pattern is fabricated by transcribing a pattern of a photomask onto the PR layer. Accordingly, the shape of the WPR pattern is affected by the characteristics of and shape of the pattern of the photomask. Therefore, the line width of the pattern the photomask must be first be uniform before any technique aimed at improving the uniformity of the line width of the WPR pattern can be effective.

FIG. 1 is a flowchart illustrating typical processes in the fabricating of a photomask. Referring to FIG. 1, a circuit pattern of a semiconductor product is designed using a computer program (such as a CAD or OPUS program). The designed circuit pattern is stored in a predetermined memory as electronic data (S10). Then, an exposure process (S20) is performed in which an electronic beam or a laser irradiates a predetermined portion of a photoresist film lying over a chrome layer on a quartz substrate. The region irradiated by the exposure process (S20) is determined by the stored design circuit pattern data. The exposed photoresist film is then developed (S30). The development process (S30) removes select portions of the photoresist film, such as those which were irradiated, to thereby form a photoresist pattern. The photoresist pattern exposes the underlying chrome film. The exposed chrome film is then plasma dry-etched using the photoresist pattern as a mask to form a mask (chrome) pattern that corresponds to the circuit pattern and, in turn, exposes the quartz substrate (S40). Then, the photoresist pattern is removed whereupon the photomask is complete.

The plasma dry etching process includes a step of generating plasma, and exposing the entire surface of the substrate to plasma such that the portions of the chrome film exposed by the photoresist pattern are removed by the plasma. However, during the etching process, the density of the plasma varies in dependence with the density of the photoresist pattern. Variations in the density of plasma, due to differences in the density of the photoresist pattern, cause a loading effect in which features of the mask pattern designed to have the same width have different widths. In addition to the loading effect associated with the etching process, the proximity effect of an electron beam used in the exposure process may cause a dimension of mask pattern to be different from the desired (design) dimension. Such a difference between the actual dimension and the design dimension impacts the yield of the semiconductor products. In the prior art shown in FIG. 1, the dose D50 of the electron beam used in the exposure process is controlled in an attempt to ensure that the actual dimension of the mask pattern corresponds to the design dimension.

However, although controlling the dose of the electron beam is totally effective in preventing a proximity effect from occurring, it is only partially effective in preventing the loading effect. This is because the loading effect occurs as the result of conditions inherent in the etching process. Also, the prior art technique of globally dry-etching etching the chrome film, in which the entire surface of the photomask method is simultaneously exposed to plasma, can hardly be controlled to prevent the loading effect from manifesting itself because the loading effect varies across the mask pattern of the photo-mask (sometimes referred to hereinafter as “in accordance with position”).

### SUMMARY OF THE INVENTION

An object of the present invention to provide a plasma etching apparatus that can be used to fabricate a pattern having a critical dimension, such as a line width, having a high degree of uniformity.

It is another object of the present invention to provide a method of fabricating a photomask that minimizes a loading effect.

It is still another object of the present invention to provide a method of fabricating a photomask using an electron beam and offsets the proximity effect of the beam.

According to one aspect of the present invention, there is provided a plasma etching apparatus capable of generating plasma, directing the plasma locally to etch a target layer, and varying the physical conditions of the plasma in accordance with the local position at which the target layer is being etched with the plasma. The plasma etching apparatus comprises a stage on which a substrate is supported, a plasma generator spaced from the stage and movable relative to the stage, a controller connected to the plasma generator to control the conditions of the plasma produced by the plasma generator, and a memory to which the controller is connected and which stores control data for controlling the physical condition of the plasma.

Preferably, the stage is movable in a given plane in one direction or two orthogonal directions, parallel to the top surface of the photomask, while the plasma generator is operated, to scan the substrate with the plasma produced by the plasma generator. Also, the plasma generator preferably comprises one or more pen-type of plasma generators. In the case of a plurality of pen-type of plasma generators, and generators are independently controlled by the controller.

A respective lower electrode may be paired with each plasma generator as disposed under the stage. Preferably, the lower electrode is electronically controlled by the controller to generate plasma having the desired physical condition. Also, the lower electrode is preferably fixed relative to the plasma generator with which it is paired.

According to another aspect of the present invention, a process gas line supplies one or more gases to the plasma generator and which gases serve as the process gas for the etching process. A flow control device for controlling the process gas is disposed in the process gas line. Also, a first power source may be provided for supplying power controlled by the controller to each plasma generator, and a second power source may be provided for supplying power controlled by the controller to each lower electrode.

According to another aspect of the present invention, there is provided a method of fabricating a photomask comprising a local etching of the mask layer. According to the method, design data of the photomask is provided and a mask film and a photoresist film are sequentially formed on a photomask substrate. Then, the photoresist film is exposed using the design data. Then, the exposed photoresist film is developed to form a photoresist pattern that exposes the mask film. Subsequently, the exposed mask film is locally etched using the photoresist pattern as an etching mask.

Preferably, pattern density data in accordance with position is extracted from the design data, and plasma condition data in accordance with position is prepared using the extracted pattern density data in accordance with position. The plasma condition data is representative of process conditions of the etch process to be controlled in accordance with the etching position. In this case, the local etching of the mask film is performed using the plasma condition data in accordance with position. Also, the plasma condition data may be generated using loading effect data in accordance with a pattern density obtained experimentally or theoretically.

According to another aspect of the present invention, the photoresist film is exposed with an electron beam and different doses of the electron beam may be used in the exposure process in accordance with the position at which the photoresist film is being irradiated by the beam. The controlling of the dosages in the exposure process may contribute to enhancing the etching uniformity. Therefore, the doses of the electron beam may be established using the loading effect data in accordance with pattern density.

According to yet another aspect oft he present invention, after the photoresist pattern is formed, a size (critical dimension) of the photoresist pattern is measured using an ADI, and data representative of the size may be stored. In such a case, the plasma condition data in accordance with position may be generated using the pattern density data in accordance with position and the stored data on the size of the photoresist pattern.

Still further, the local etching may be carried out by an etching apparatus including a plasma generator, an upper electrode, a lower electrode, and a gas supply line for supplying one or more gases to the plasma generator. In such a case, the physical condition of the plasma is controlled by at least one process of controlling the power applied to the upper electrode, controlling the power applied to the lower electrode, and controlling the kinds of gases supplied to the plasma generator, the flow rates of the gas or gases supplied, and/or the composition of the process gas (ratio of the gases supplied to the plasma generator).

### BRIEF DESCRIPTION OF THE DRAWINGS

These and other objects, features and aspects of the present invention will be better understood from the detailed description of the preferred embodiments thereof that follows as made with reference to the accompanying drawings In the drawings:

FIG. 1 is a flowchart of a prior art process of fabricating a photo-mask;

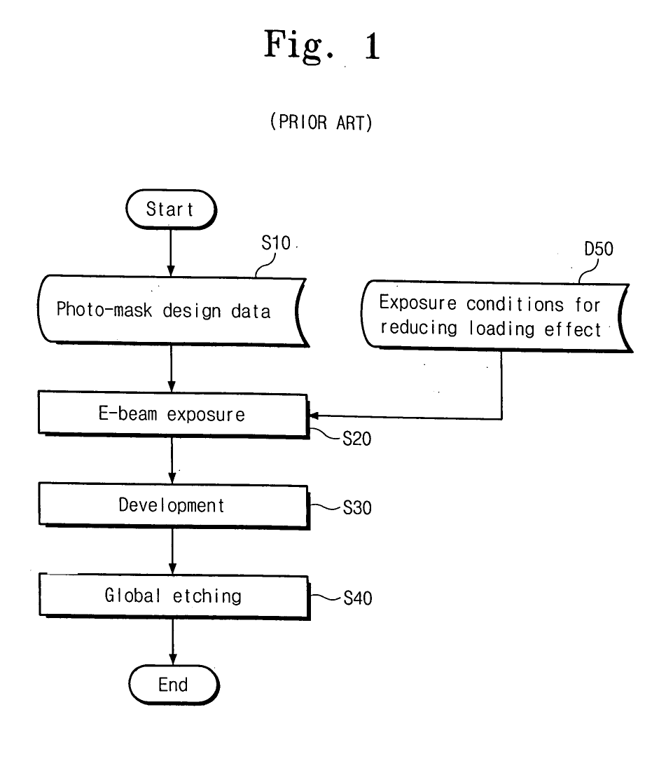

FIG. 2 is a flowchart of a first embodiment of a process of fabricating a photomask according to the present invention;

FIG. 3 is a flowchart of a second embodiment of a process of fabricating a photomask according to the present invention;

FIG. 4 is a flowchart of a third embodiment of a process of fabricating a photomask according to the present invention;

FIG. 5 is a flowchart illustrating a method of generating the plasma condition data for use in the processes of FIG. 4;

FIG. 6 is a schematic diagram of a plasma etching apparatus according to the present invention;

FIG. 7 is a perspective view of a first embodiment of a plasma generator according to the present invention; and

FIG. 8 is a perspective view of a second embodiment of a plasma generator according to the present invention.

### DETAILED DESCRIPTION OF THE PREFERRED EMBODIMENTS

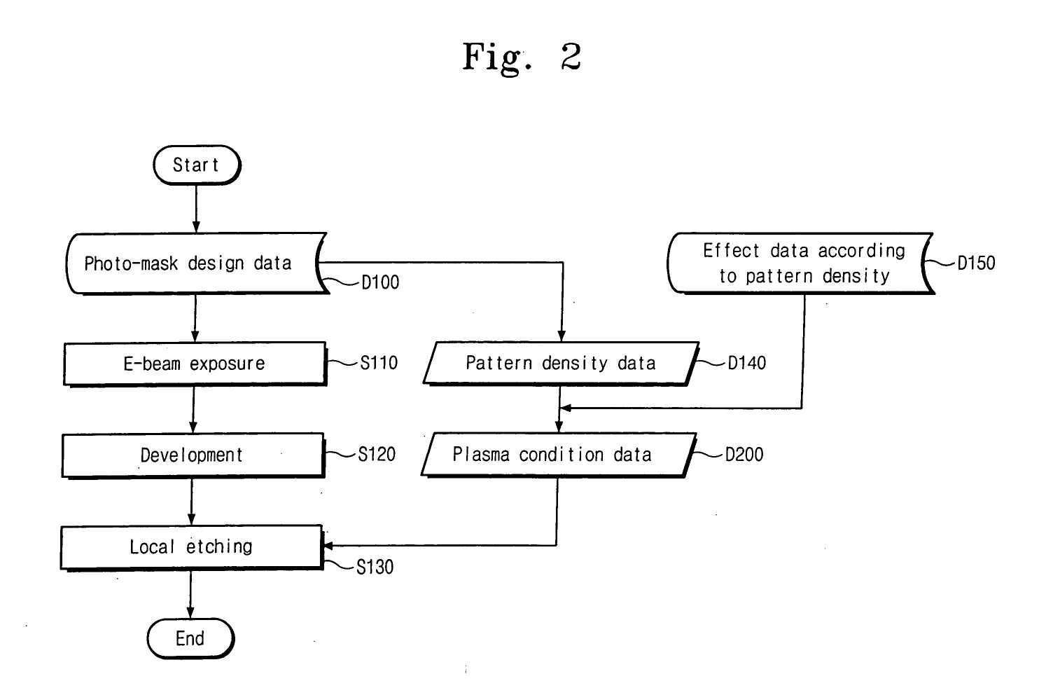

Referring to FIG. 2, a circuit pattern of a semiconductor device is designed using a computer program such as a CAD or OPUS program. The circuit pattern is stored in a memory as electronic data D100. The electronic data D100 is inputted to a controller of an exposure apparatus of the photolithography equipment used for making a photo-mask. A test for determining whether the design represented by the electronic data D100 has defects is preferably performed before the design data is inputted to the controller.

The exposure apparatus performs an exposure process in which a predetermined region of a photo-resist film formed on a photomask substrate is irradiated using an electron beam or a laser (S100). A quartz substrate is commonly used as the photo-mask substrate. The region irradiated in the exposure process S110 is determined by the design data D100 input to the controller of the exposure apparatus.

The exposed photoresist film undergoes a development process (S120) to form a photoresist pattern that exposes a film thereunder. The film may comprise at least one layer of material selected from a group consisting of Cr, MoSi, an IV-transition metal nitride, a V-transition metal nitride, a VI-transition metal nitride, and silicon nitride.

The exposed film is locally etched using the photoresist pattern as an etching mask to form a film pattern that exposes the top surface of the photomask substrate (S130). According to the present invention, the etching (S130) is performed by scanning the substrate with plasma and varying the process conditions in accordance with the position of the scan. In this respect, the plasma etching is carried out using plasma condition data D200 generated using the design data D100.

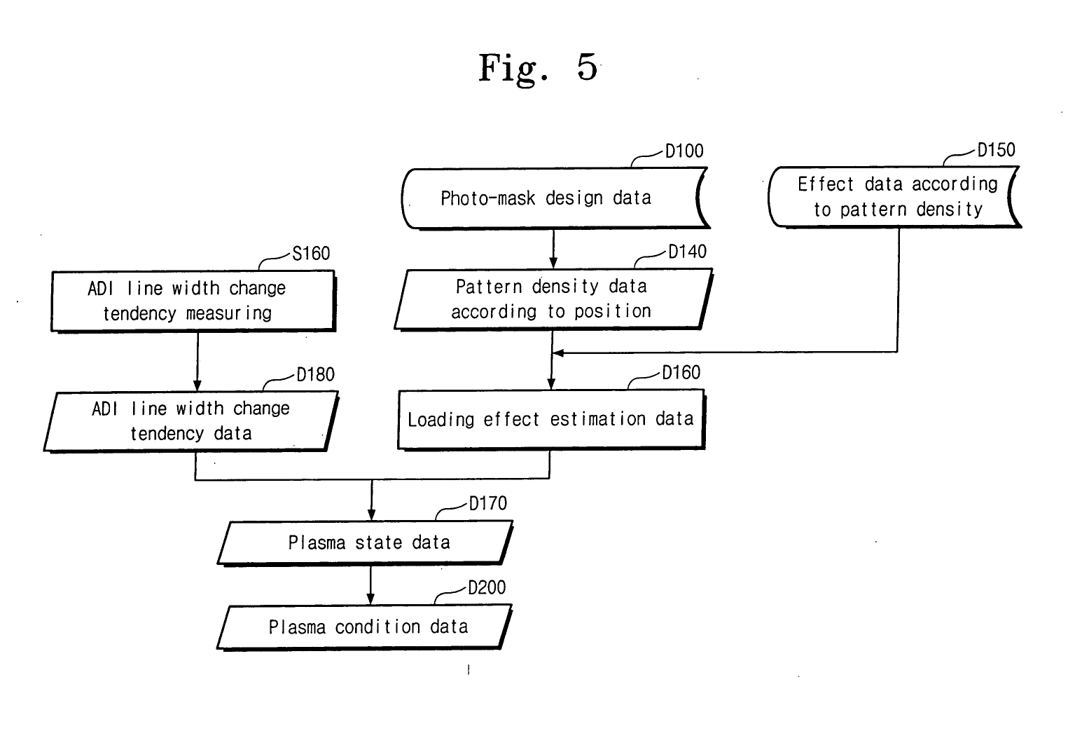

More specifically, the plasma condition data D200 is generated by extracting pattern density data D140 from the design data D100 using a predetermined computer program (refer to FIG. 5). The pattern density data is representative of the pattern densities of various regions of the photo-mask pattern as correlated with the relative position of the regions on the photo-mask. The pattern density data D140 is analyzed using loading effect data D150 developed in accordance with a pattern density obtained experimentally or theoretically. Such an analysis is performed using a predetermined computer program and the results of the analysis may be electronically stored as loading effect estimation data D160. The loading effect estimation data D160 represents the extent to which the loading effect will occur at the various positions across the photomask. The loading effect estimation data D160 may be used for extracting plasma state data D170 that specifies the physical state of plasma required for preventing the loading effect from occurring. The extracted plasma state data D170 may be used for extracting the plasma condition data D200 that specifies the process conditions required for generating plasma having such a physical state.

According to the present invention, the etching process (S130) is performed using a plasma generator that can generate plasma under different process conditions. Also, the plasma generator can locally expose the surface of the photomask to the plasma. The plasma generator is controlled in accordance with the plasma condition data D200. As a result, it is possible to alleviate the loading effect that would otherwise cause non-unifornity in the etching process due to variations in the density of the photoresist pattern.

The photoresist pattern is removed after the etching process. Then, the photomask is washed. The photo-mask formed by such a process is then inspected to determine whether a value of the dimensions of the mask pattern is smaller than a predetermined value. A photomask that passes such an inspection is delivered as a final product.

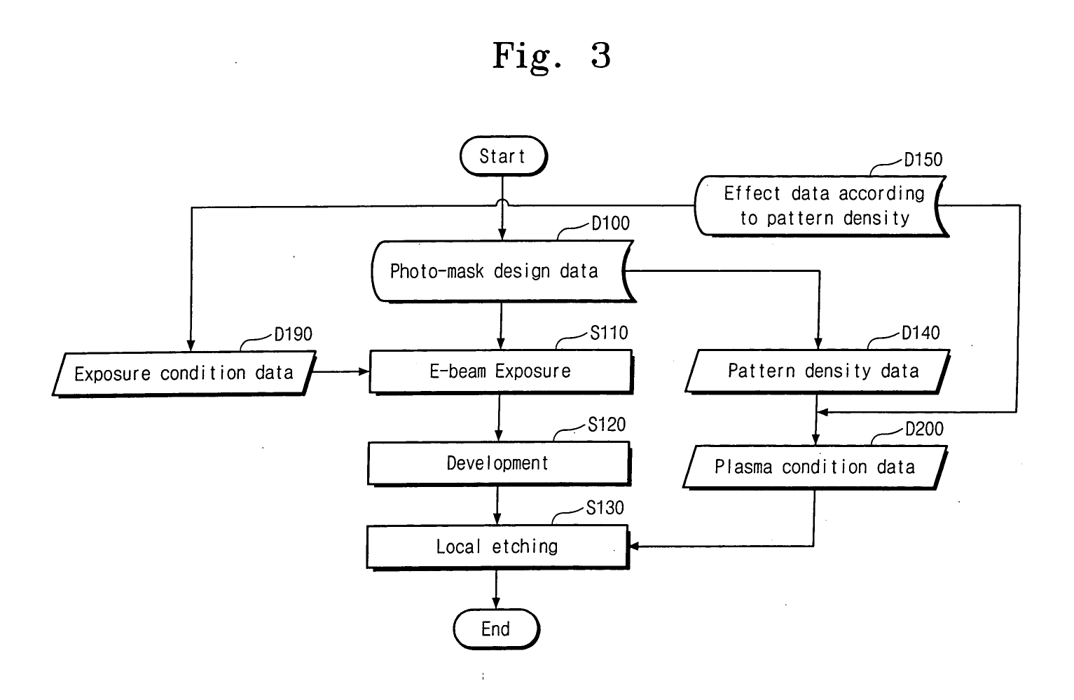

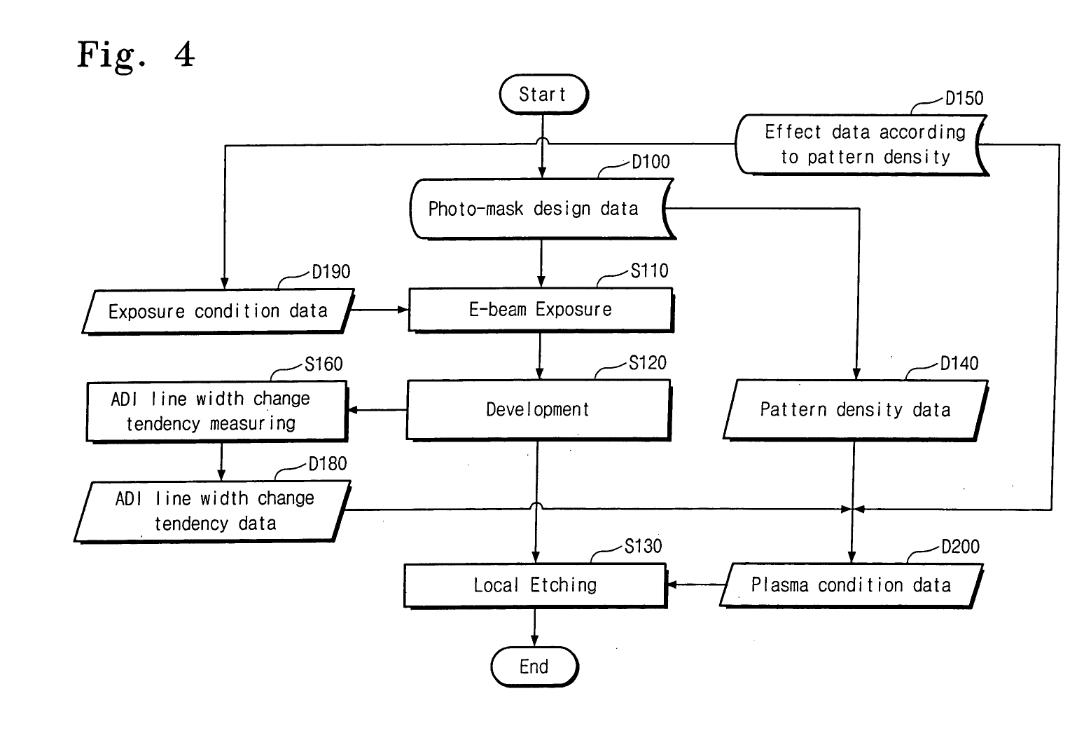

FIGS. 3 and 4 illustrating processes of fabricating photo-masks according to second and third embodiments of the present invention. Aspects of these embodiments similar to that of the above-described first embodiment will not be described.

Referring to FIG. 3, the second embodiment of the present invention includes a step of correcting the process conditions of the exposure process using predetermined exposure condition data D190. In general, the exposure condition data D190 is for minimizing the proximity effect created by an electron beam and may include data that specifies the dose of the electron beam in accordance with the position on the substrate at which the exposure process is carried out.

According to the present invention, the exposure condition data D190 may include data for minimizing the loading effect generated during the etching process (S130). For example, the exposure condition data D190 is determined considering the loading effect data D150 and the influence that the exposure process (S110) has on the etching process (S130). The exposure condition data D190 is preferably data that defines the process conditions of the exposure process (S110) in accordance with position considering that the exposure condition data D190 is produced to offset the loading effect in accordance with the pattern density. In such a case, therefore, the exposure condition data D190 combines the data on the respective conditions for correcting for the proximity effect and the loading effect.

Referring to FIGS. 4 and 5, the third embodiment of the present invention includes a step of performing the etching process (S130) based on tendencies of the development process (S120) to affect the line width of the photoresist pattern.

In general, an after-develop-inspection (ADI) (S160) is performed before the etching process (S130). The after-develop-inspection (ADI) examines whether the features of the photoresist pattern have dimensions, e.g., line widths, within certain design tolerances. The line widths of the mask pattern correspond to those of the photoresist pattern, measured in the ADI step (S160) because the mask pattern is formed by etching a film using the photoresist pattern as a mask. Therefore, data measured in the ADI (S160) is preferably reflected in the plasma condition data D200 in order to ensure uniformity in the line width of the mask pattern.

In addition, the ADI (S160) measures the developed line width of the photoresist pattern locally, i.e., not over the entire surface of the photo-mask. Therefore, the measurements made in the ADI (S160) should be tempered with information on the tendency of the line width of the photoresist pattern to vary across the substrate (i.e., in accordance with position). That is, the line width of the photoresist pattern varies in accordance with position due to factors associated with the depositing/developing/baking of the photoresist. In general, the line width of the photoresist pattern varies in a radial direction from the center of the photomask, and along the edge of the photo-mask.

According to the third embodiment of the present invention, data D180, representative of the tendency of the line width of the photoresist pattern to vary in accordance with position, may be used to generate the plasma state data D170. That is, the plasma state data D170 may serve to offset the tendency of the line width of the photoresist pattern to vary in accordance with position as well as to suppress the loading effect. In particular, the plasma state data D170 may be used for extracting the plasma condition data D200 that specifies process conditions required for generating plasma having a physical state which will create a mask pattern having a uniform line width despite variations in the line width of the photoresist pattern used as the etch mask, and which will suppress the loading effect.

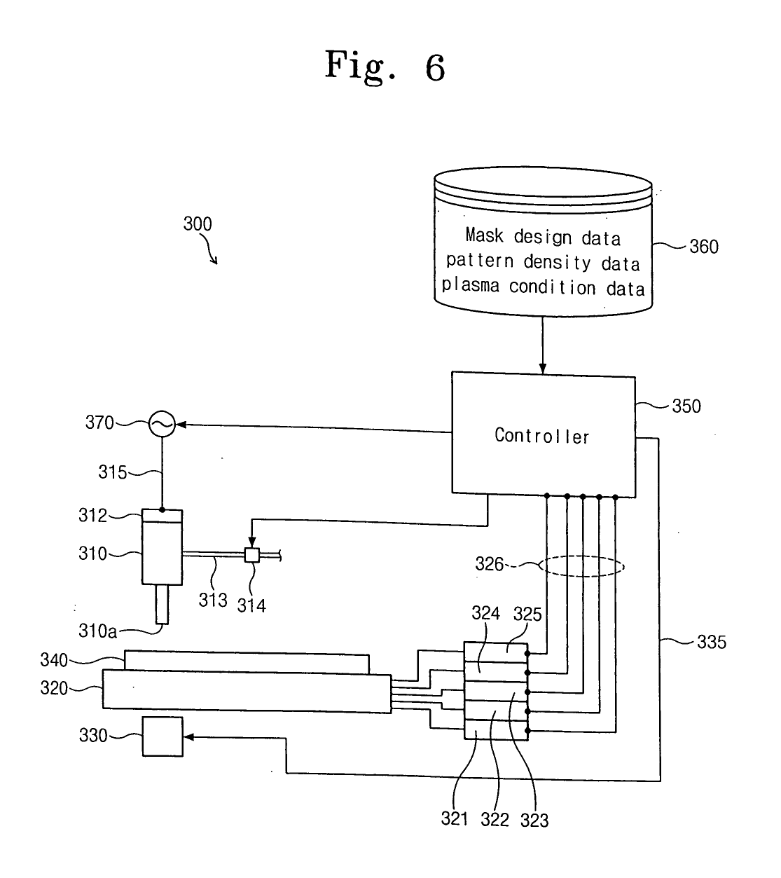

FIG. 6 illustrates a plasma etching apparatus 300 according to the present invention. Referring to FIG. 6, the plasma etching apparatus includes a plasma generator 310, a stage 320, a controller 350, and a memory 360. An intermediate photomask product, referred to as a “photomask” 340 although not complete, is loaded on the stage 320 and the plasma generator 310 is positioned over the photomask 340.

The plasma generator 310 forms plasma locally at the top of the photomask 340. To this end, the plasma generator 310 is spaced a predetermined distance from the top surface of the photomask 340 and a discharge hole 310a of the plasma generator through which plasma is discharged has a small area. Also, one or more process gases are supplied to the plasma generator 310 through a process gas line 313. The process gas may be at least one gas selected from a group consisting C₁₂, O₂, Ar, He, Ne, and Xe. A flow control device 314 controlled by the controller 350 is disposed in the process gas line 313. The controller 350 controls the flow control device 314 to control the types and flow rates of the gases, and hence the composition of the process gas, supplied to the plasma generator 310

Also, the plasma generator 310 may include an upper electrode 312 for ionizing the process gas. The upper electrode 312 is connected to a radio frequency (RF) power supply 370. The RF power supply 370 is controlled by the controller 350. The controller 350 electronically controls the output of the RF power 370 supply to control the physical state of the plasma.

An X-axis stage 321, a Y-axis stage 322, a Z-axis stage 323, a θ stage 324, and a leveling stage 325 may be mechanically connected to the stage 320 for controlling the position, angular orientation and leveling of the stage 320. The stages 321, 322, 323, 324, and 325 are electronically connected to the controller 350 through stage control lines 326. In particular, the X- and Y-axis stages 321 and 322 include precise motors which can be controlled by the controller 350 so that the stage 320 can be moved in orthogonal directions, whereby the plasma generator scans the photomask 340 mounted to the stage. In this case, the stage 320 preferably moves in a plane parallel to the top surface of the photo-mask 340.

A lower electrode 330 may be disposed under the stage 320. The lower electrode 330 is preferably arranged under the plasma generator 310. The lower electrode 330 accelerates ions generated by the plasma generator 310 towards the photomask so as to enhance the ability of the ions to etch the film formed on the substrate of the photomask 340. The power applied to the lower electrode 330 is electronically controlled by the controller 350. Also, the lower electrode 330 may be movable along with the plasma generator 310. That is, the relative position between the lower electrode 330 and the plasma generator 310 is fixed.

The controller 350 is electronically connected to a memory 360 in which plasma condition data is stored. The plasma condition data specifies process conditions for controlling the physical state of the plasma generated by the plasma generator 310 for each position at which the photomask 340 is etched. For instance, the specified process conditions include the power output by the RF power supply 370, the power applied to the lower electrode 330, and the conditions established by the flow control device 314. Various other forms of data, such as mask design data, pattern density data, and loading effect data in accordance with pattern density, may also be stored in the memory 360 (refer to the description of FIG. 5 with respect to such data).

According to the present invention, the etching of the film that will form the mask pattern of the photomask 34o is controlled on the basis of the plasma condition data stored in the memory 360. The plasma condition data may be generated as described with respect to any of FIGS. 2 through 4. At this time, the plasma generator 310 generates plasma locally and the stage 320 is moved during the etching process to thereby scan the plasma generator 310 and hence, the plasma, across the photomask 340. Also, a physical condition(s) of the plasma, such as its density, is/are varied in accordance with the position of the photomask 340. Thus, the etching process is controlled in accordance with the position at which the mask layer of the photomask 340 is being etched.

In particular, the etching process is controlled to prevent the loading effect from occurring and/or to offset the tendency of the line width to differ from the design line width as the result of factors inherent in the processes of depositing/developing/baking the photoresist (as revealed by an ADI inspection).

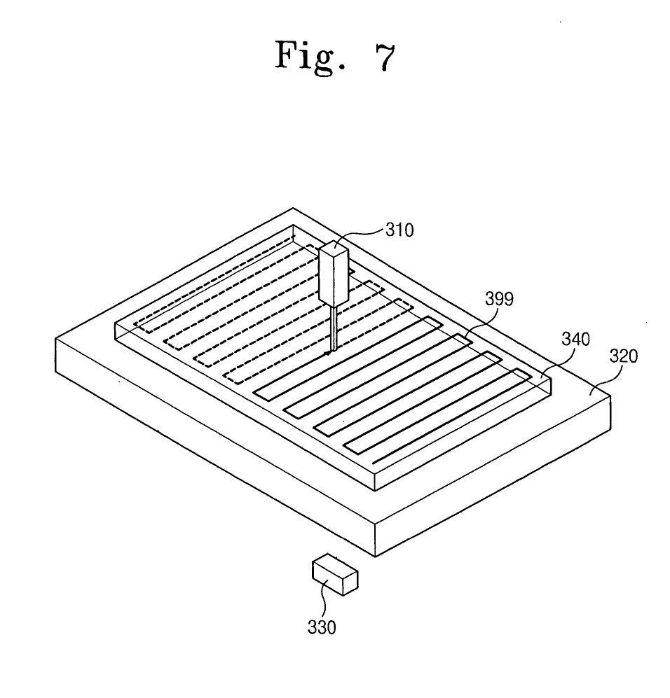

Referring to FIG. 7, the plasma generator 310 may be a pen-type of plasma generator whose outlet is in the form of a stylus, i.e., an elongate narrow tube. In such a case, the plasma generator 310 must scan the entire top surface of the photo-mask 340 in two dimensions to etch the photomask 340. At this time, the trajectory 399 of the scan is determined considering a mesh based on the density and size of plasma. The plasma condition data includes information on the density, size, mesh, and trajectory of the scan.

Although the etching apparatus of present invention has been described above a s having a fixed plasma generator 310 and movable stage 320, the plasma generator 310 may be movable while the stage 320 remains fixed. In such a case, the etching apparatus includes appropriate position control devices for controlling the position of the plasma generator 310 and the position of the lower electrode 330.

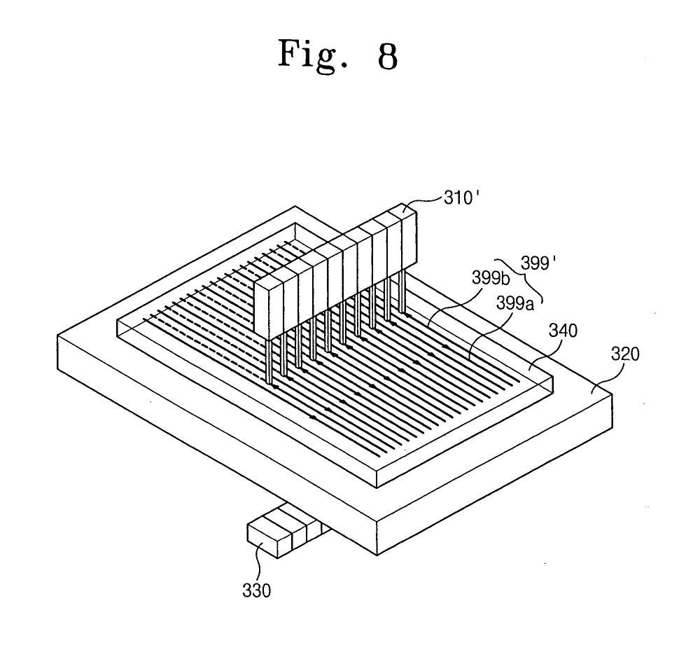

According to another embodiment of the present invention as shown in FIG. 8, a plurality of plasma generators 310′ are arranged in parallel (side-by-side) above the stage 320 and photomask 340. The extent over which the plasma generators 310′ are disposed in parallel preferably corresponds to the length of one side of the photomask. Thus, the scanning direction is preferably in one direction, i.e., perpendicular to the direction in which the plasma generators 310′ are arranged. However, the plasma generators 310′ maybe controlled such that they execute a scan of the entire top surface of the photo-mask 340 in two parallel directions.

The trajectories 399′ of the scan are determined considering the density, size, and mesh of plasma. For example, the etching process may include a first scanning step whose trajectories 399a extend in one direction and a second scanning step whose trajectories 399b extend in the opposite direction. In such a case, the trajectories 399a of the first scanning step lie between the trajectories 399b of the second scanning step as illustrated in the figure. This embodiment, comprising a plurality of plasma generators 310′, can provide a greater productivity than the preceding embodiment which comprises only one plasma generator.

Also, according to this embodiment, the physical conditions of the plasma generated by the respective plasma generators 310′ must be separately controlled. To this end, each of the plasma generators 310′ may include a respective upper electrode 312 and/or process gas line 313 (FIG. 6), and the controller 350 separately controls the upper electrodes 312 and/or the flow control devices 314 in process gas lines 313. Data for such separate control is stored in the memory 360 as plasma condition data.

According to the present invention, a plasma etching apparatus for variably etching local regions of a mask film of a photo-mask is provided. Therefore, it is possible to provide different etching conditions in accordance with position in the fabricating of a photomask to thereby prevent the loading effect and thus, ensure uniformity in the line width of the mask pattern. Furthermore, the plasma etching apparatus according to the present invention may be used for offsetting the tendency of variations in the line width of the photoresist pattern to effect the uniformity of the line width of the mask pattern when the photoresist pattern is used as an etch mask. As a result, it is possible to fabricate a photomask whose line width is remarkably uniform.

Finally, although the present invention has been described above in connection with the preferred embodiments thereof, the present invention is not so limited. Rather, various changes in and modifications of the preferred embodiments will be readily apparent to those of ordinary skill in the art. Accordingly, those and other changes and modifications are seen to be within the true spirit and scope of the invention as defined by the appended claims.

1. A plasma etching apparatus comprising:
a stage on which a substrate is to be supported;
at least one plasma generator that generates plasma and spaced from said stage at one side thereof, said plasma generator and said stage being supported in the apparatus so as to be movable relative to each other, whereby a substrate supported by the stage can be scanned by the plasma generator;
a memory that stores plasma condition data representative of physical conditions of plasma; and
a controller connected to the memory and to the plasma generator to control the plasma generator to generate plasma having physical conditions based on the plasma condition data.

2. The plasma etching apparatus as set forth in claim 1, wherein said stage is movable in at least one direction in a given plane, and said plasma generator is fixed in place in the apparatus.

3. The plasma etching apparatus as set forth in claim 1, wherein the at least one plasma generator comprises at least one pen-type of plasma generator having an outlet in the form of a stylus.

4. The plasma etching apparatus as set forth in claim 3, wherein the at least one plasma generator comprises one pen-type of plasma generator, and the stage is movable in two orthogonal directions in said plane.

5. The plasma etching apparatus as set forth in claim 3, wherein the at least one plasma generator comprises a plurality of said pen-type of plasma generators, and each of said pen-type of plasma generators is respectively connected to the controller so as to be independently controlled by the controller.

6. The plasma etching apparatus as set forth in claim 1, and further comprising a respective lower electrode paired across from each said at least one plasma generator on the other side of the stage, and wherein each said lower electrode is electronically connected to the controller.

7. The plasma etching apparatus as set forth in claim 6, wherein each respective said lower electrode is fixed relative to the plasma generator with which it is paired.

8. The plasma etching apparatus as set forth in claim 1, further comprising:
a process gas line connected to the plasma generator and through which process gas is supplied to the plasma generator;
a flow control device disposed in the process gas line to control the amount of the process gas flowing to the plasma generator; and
a power source associated with the plasma generator and electronically connected to the controller so as to supply power controlled by the controller to the plasma generator.

9. The plasma etching apparatus as set forth in claim 6, further comprising:
a process gas line connected to the plasma generator and through which process gas is supplied to the plasma generator;
a flow control device disposed in the process gas line to control the amount of the process gas flowing to the plasma generator;
a first power source associated with the plasma generator and electronically connected to the controller so as to supply power controlled by the controller to the plasma generator; and
a second power source connected to the lower electrode and electronically connected to the controller so as to supply power controlled by the controller to the lower electrode.

10. A method of fabricating a photomask, comprising:
providing design data of a photomask to be fabricated, the design data representative of a mask pattern of the photomask;
sequentially forming a mask film and a photoresist film on a photomask substrate;
exposing the photoresist film using the design data;
developing the exposed photoresist film to form a photoresist pattern that exposes the mask film; and
locally etching the exposed mask film using the photoresist pattern as an etching mask.

11. The method as set forth in claim 10, further comprising:
extracting pattern density data in accordance with position from the design data, the pattern density data in accordance with position being representative of the densities of the mask pattern at various regions of the photomask pattern as correlated with the relative position of the regions of the photomask; and
generating plasma condition data in accordance with position using the extracted pattern density data in accordance with position, the plasma condition data in accordance with position being representative of conditions of plasma to be generated at the various regions of the photomask, and
wherein the local etching of the mask film is performed using the plasma condition data in accordance with position.

12. The method as set forth in claim 11, and further comprising developing loading effect data in accordance with a pattern density obtained experimentally or theoretically,
the loading effect data representing differences in the line widths of features of the mask pattern, designed to have the same line width, which result from differences in the density of the photoresist pattern when the mask layer is etched using the photoresist pattern as an etch mask, and
wherein the plasma condition data is generated using the loading effect data.

13. The method as set forth in claim 10, wherein the exposing of the photoresist film comprises irradiating the photoresist film with an electron beam, and setting the dose of the electron beam in accordance with the position at which the photoresist film is being irradiated by the beam.

14. The method as set forth in claim 13, and further comprising developing loading effect data in accordance with a pattern density obtained experimentally or theoretically,
the loading effect data representing differences in the line widths of features of the mask pattern, designed to have the same line width, which result from differences in the density of the photoresist pattern when the mask layer is etched using the photoresist pattern as an etch mask, and
wherein the dose of the electron beam is set using the loading effect data.

15. The method as set forth in claim 11, further comprising:
measuring a critical dimension of the photoresist pattern; and
storing data on the measured critical dimension, and
wherein the plasma condition data is generated using the pattern density data in accordance with position and the data on the critical dimension of the photoresist pattern.

16. The method as set forth in claim 10, wherein the local etching of the mask film comprises scanning the substrate in at least one direction in a given plane with plasma.

17. The method as set forth in claim 10, wherein the local etching of the mask film is performed using a plasma generator comprising an upper electrode, a lower electrode, and a gas supply line through which process gas is supplied to the plasma generator, and comprises controlling at least one of the power applied to the upper electrode, the power applied to the lower electrode, and the process gas supplied to the plasma generator through the gas supply line.
